(19) United States
(12) Patent Application Publication
(10) Pub. No.: US 2019/0391193 A1
(43) Pub. Date: Dec. 26, 2019

(54) An interferometric IQ-mixer/DAC solution for active, high speed vector network analyser impedance renormalization

(71) Applicant: VERTIGO TECHNOLOGIES B.V., Delft (NL)

(72) Inventors: Marco Spirito, The Hague (NL); Luca Galatro, Delft (NL); Raffaele Romano, Delft (NL); Faisal Ali Mubarak, Delft (NL)

(73) Assignee: Vertigo Technologies B.V., Delft (NL)

(21) Appl. No.: 16/480,711

(22) PCT Filed: Jan. 25, 2018
(86) PCT No.: PCT/NL2018/050055

§ 371 Date: Jul. 25, 2019

(30) Foreign Application Priority Data
Jan. 25, 2017 (NL) 2018225

(51) Int. Cl. G01R 27/28; G01R 31/28; G01R 31/319; G01R 23/02

(52) U.S. Cl. CPC G01R 27/28; G01R 31/2822; H03D 3/009; G01R 23/02; G01R 31/31901

(57) ABSTRACT

Device under test (DUT) interface device for use in a system for executing measurements on a device under test (9) with a vector network analyser (11).

The DUT interface device comprises a divider/coupler component (4), a variable gain amplifier (5), an I/Q mixer (6) and a bridge/coupler component (7) and provides a test signal (a) to the DUT terminal (3).

The system further comprises a control unit (12) connected to the vector network analyser (11) and to control input terminals (8) of associated ones of the at least one DUT interface device (1). The control unit (12) provides quadrature control signals (V_{I}, V_{Q}) for the associated at least one DUT interface device (1), which are connected directly to the device under test (9). The present invention further relates to proper calibration and measurement methods.

### FIELD OF THE INVENTION

The present invention relates to an interface device for connecting a vector network analyser to a device under test (DUT), and in a further aspect to a system for executing measurements on a device under test comprising a vector network analyser, and at least one DUT interface device according to an embodiment of the present invention. Furthermore, the present invention relates to a method for using such a system.

### BACKGROUND ART

In the article by G. Vlachogiannakis et al., “An I/Q-Mixer-Steering Interferometric Technique for High-Sensitivity Measurement of Extreme Impedances”, International Microwave Symposium, May 2015, a vectorial signal cancellation technique based on IQ phase steering is disclosed for measurements on a device under test using a vector network analyser (VNA). The disclosed system uses a splitter on the path of the a₁ signal, internally to the VNA. This implementation results in the fact that the signal driving the LO of the IQ mixer and the signal driving the DUT, propagate on different transmission lines, i.e., cables. This makes this setup very sensitive to relative phase fluctuation between the two signals, hampering the cancellation condition. Moreover, to feed back the signal inside the VNA after the splitter, allows to realize signal cancellation only for a subset of VNA's, namely the ones providing front jumpers. In the implementation disclosed in this article no synchronization between the VNA source and the DAC controlling the injection vector was realized, making frequency sweep slow since it is performed one frequency point at the time. Also, this prior art implementation used a resistive divider to create the injection signal, this solution provides no isolation between the main line and injection path, making the cancellation condition susceptible to mismatches along the lines causing reflected signals coupling on the other signal path (i.e., from main to injection path and vice versa). Furthermore, in this prior art implementation there is no capability of decoupling the power level of the main path from the one driving the IQ mixers (of passive type in the mentioned implementation) requiring a specific LO power level. This makes this prior art solution capable to operate only at fixed power level, modifying the power requires changes on the setup by means of mechanical attenuators. Finally, this prior art implementation does not consider active amplification after the IQ mixer, thus often using the mixer in the non-optimal (linear) region, since the amplitude of the injected vector is only defined by the IQ signals.

### SUMMARY OF THE INVENTION

The present invention seeks to provide improved test set-up arrangements for high frequency measurements of (active) devices (device under test, DUT), which is less susceptible to distortions and more robust during operation, especially suited for devices having a high reflection coefficient (Γ). In present measurement systems and methods, such a high Γ DUT will usually result in problems for performing accurate and repeatable measurements.

According to the present invention, a device under test (DUT) interface device is provided as described above, wherein the DUT interface device comprises an analyser terminal, a DUT terminal and a control input terminal, a divider/coupler component having a main terminal connected to the analyser terminal, a variable gain amplifier connected to a first branch terminal of the divider/coupler component, an I/Q mixer having an input terminal connected to an output terminal of the variable gain amplifier, a bridge/coupler component, of which first branch terminals are connected between a second branch terminal of the divider/coupler component and the DUT terminal for providing a test signal a to the DUT terminal, and second branch terminals are connected between an output of the I/Q mixer and a grounding impedance. This set-up allows the DUT interface device to be positioned directly adjacent the DUT, and as a result the components of the DUT interface device as well. This results in a much lower susceptibility to external distortions and hence better performance of actually testing a DUT, especially when the DUT has a high Γ coefficient.

In a further aspect, the present invention relates to a system as defined above, wherein the DUT interface device is connected to an associated measuring port of the vector network analyser. The system further comprises a control unit connected to the vector network analyser and to control input terminals of associated ones of the at least one DUT interface device, wherein the control unit is arranged to provide quadrature control signals for the associated at least one DUT interface device. The at least one DUT interface device is connected directly to the device under test DUT. In a further aspect the (DC) quadrature control signals are generated by a digital to analogue converter and can vary synchronously to the frequency of the vector network analyser through a hardware trigger loop, allowing quasi real time frequency sweeps with signal cancellation.

In an even further aspect, the present invention relates to a method for using a system according to an embodiment of the present invention, wherein the system comprises a DUT interface device connected to a first measuring port of the vector network analyser. The method comprises calibrating the system by obtaining injection signal parameters and vector calibration coefficients to allow measurements of a device under test connected to the DUT interface device. The method comprises a calibration part wherein the proper injection signals for the DUT interface devices are determined, and optionally an actual measurement step, in which the proper injection signals are used, and which make the method especially suitable for a DUT having a high Γ coefficient.

### SHORT DESCRIPTION OF DRAWINGS

The present invention will be discussed in more detail below, with reference to the attached drawings, in which

FIG. 1 shows a schematic diagram of a prior art test set-up using an interferometric technique;

FIG. 2 shows a further prior art DUT set-up arrangement using an interferometric technique;

FIG. 3 shows a schematic diagram of an embodiment of a DUT interface device according to an embodiment of the present invention;

FIG. 4 shows a schematic diagram of a test set-up arrangement according to a further aspect of the present invention;

FIG. 5A-5C show flow charts of calibration/measurement method embodiment groups as used for the test set-up arrangement of FIG. 4;

FIG. 6 shows a flow chart for a test sequence using the test set-up arrangement of FIG. 4.

### DESCRIPTION OF EMBODIMENTS

High frequency devices are characterized by their reflection (Γ) and transmission coefficients when driven from input and/or output, often represented in the S-parameter formalism when a vector correction is applied to the measurement instrument. Characterization of the device under test (DUT exhibiting a large voltage standing wave ratio (VSWR) condition, i.e.

(1+|Γ|)/(1−|Γ|)>9,

(representing a |Γ|=0.8 and real impedances smaller than 5.5Ω and larger than 450 Ω),

result in an increased uncertainty of the measured impedance (i.e., Z), i.e., higher than two order of magnitude compared to the zero VSWR case. Thus, extreme impedances (i.e., falling under the VSWR>9 category), in respect to the system impedance (generally 50Ω), present a big challenge for high frequency characterization.

The reason for this can be easily found observing the relation between the device impedance and the instrument measured parameter, i.e., Γ vs. Z. For impedance levels between a few Ω's and a few hundredths Ω's the derivative of the reflection coefficient versus impedance (δ Γ/δZ) is high, resulting in a compression of the measured noise. When the impedance levels are shifted to the ones providing a VSWR larger than 9 the δ Γ/δZ derivate approaches zero, resulting in an expansion of the measured noise providing large uncertainty in DUT impedance value. E.g. the relative uncertainty of the measured impedance may increase more than two orders of magnitudes for impedance levels lower than 5.5Ω and higher than 450Ω. In order to provide low uncertainty measurements under high VSWR conditions, various techniques have been proposed to cancel the large reflecting wave scattered by the DUT during testing, i.e., transforming the device back to a low VSWR case. These techniques can be grouped based on the implemented method:

1) matching approaches (i.e., transforming the impedance using passive elements),

2) interferometric techniques, i.e., cancelling the reflected signal with a signal with similar amplitude and opposite phase.

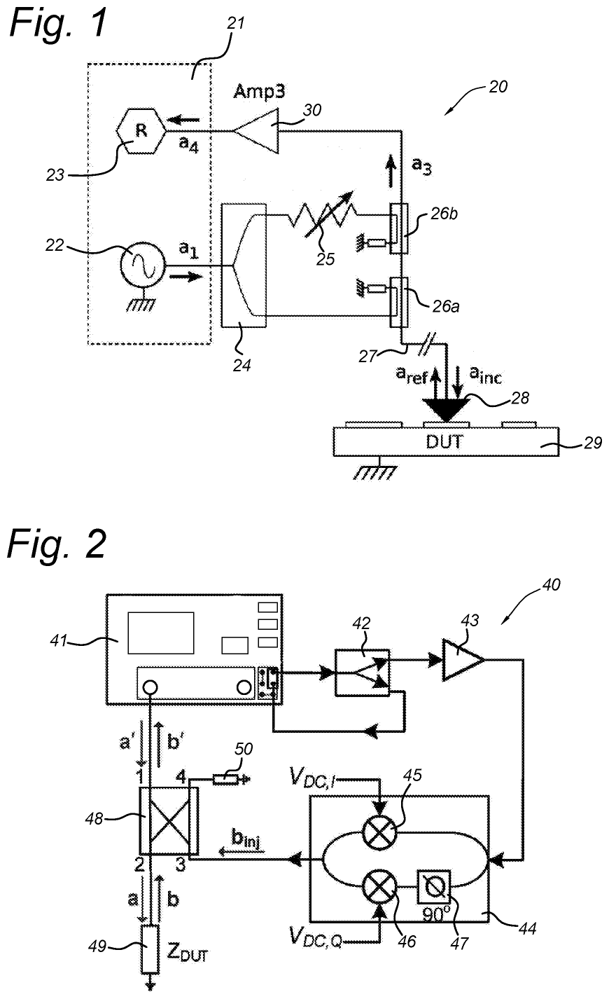

Several interferometric techniques to achieve impedance renormalization of a one-port VNA are known in the art. An exemplary test set-up using a network analyser 21 is shown in the schematic view of FIG. 1. The driving signal a₁ in FIG. 1 originating from oscillator 22 is first split in two equal-power branches using splitter 24. One of the splitter branches is used to drive the DUT 29 through a directional coupler 26a in order to provide an incoming signal a_{inc} at the plane 28 of the DUT 29. The reflected signal a_{ref1} is then fed back via a (phase shifting) cable 27. The other branch of the splitter 24 is connected to a variable attenuator 25 and used as a cancellation signal using an upper directional coupler 26b. The cancellation signal is combined with the reflected signal a_{ref} from the DUT 29 creating the (low level) signal a₃. This signal a₃ is amplified using amplifier 30 and input as measurement signal a₄ to a receiver input 23 of the network analyser 21.

The large electrical distance between the injection point of the cancellation signal (at the upper directional coupler 26b) and the DUT 29 (i.e., due to cables 27 and two directional couplers 26a, 26b) makes the cancellation condition extremely sensitive to system variations (i.e., phase and amplitude due to cable 27 movements and temperature fluctuations). Moreover the use of only a variable attenuator 25 makes the cancellation condition possible only at specific frequencies i.e., frequencies at which the phase of the injected signal is opposite to the phase of the reflected signal at the plane of a₃.

As mentioned above, in the article G. Vlachogiannakis, H. T. Shivamurthy, et al., “An I/Q-Mixer-Steering Interferometric Technique for High-Sensitivity Measurement of Extreme Impedances”, International Microwave Symposium, May 2015, an interferometric (cancellation) technique based on IQ phase steering is disclosed. FIG. 2 shows a schematic diagram of a test set-up 40 using this interferometric technique. The system uses a splitter 42 on the path of the a₁ signal (i.e. the generated test signal), external to the (vector) network analyser, VNA, 41. In FIG. 2 the splitter 42 is shown as being implemented external to the VNA 41, requiring suitable front terminals (jumpers) on the VNA 41 to allow feedback of the (split) signal to the VNA 41. The other part of the (split) signal from splitter 42 is fed to an amplifier 43 as an input to an IQ mixer 44. Under control of two control voltages V_{DC,I} and V_{DC,Q} and two mixers 45, 46 and a phase shifter 47 as internal components of the IQ mixer 44, an injection signal bᵢₙⱼ is provided to a coupler 48. The other ports of the coupler 48 are connected to the VNA 41 port (receiving the a′ signal), a terminating impedance 50, and the DUT 49 (depicted as impedance Z_{DUT}).

This implementation of the test set-up 40 results in the fact that the signal driving the LO of the IQ mixer 44 and the signal driving the DUT 49, propagate on different transmission lines, i.e., cables. This makes this setup very sensitive to relative phase fluctuation between the two signals, hampering the cancellation condition, since small variations on large vectors cause a large residual vector difference which corresponds to the b′ wave in FIG. 2. Moreover, splitting the signal, and feeding back the signal inside the VNA 41, allows to realize impedance normalization only for a subset of VNAs, namely the ones providing front jumpers. The usage of a resistive splitter does not provide isolation arising from mismatches at the input port of PA 43, increasing the unwanted coupling between the signal driving the DUT 49 and the LO of the IQ mixer 44. Furthermore, the mentioned implementation does not provide the capability to vary the power driving the DUT 49 without modifying the setup, i.e., changing the attenuation/amplification to the IQ mixer 44, since the LO port of the mixer needs to be driven at the proper power level to optimize performance, (e.g. with respect to conversion losses). The amplitude of the cancellation vector is directly set from the V_{DC,I} and V_{DC,Q} signals, imposing a larger linearity from the IQ mixer and making the cancellation algorithm more sensitive due to amplitude to phase non-linearities arising from the mixer (AM to PM conversion). Finally, in the implementation of FIG. 2 no hardware synchronization between the VNA 41 source and the DAC controlling the injection vector V_{DC,I} and V_{DC,Q} was realized, making frequency sweep slow since it is performed one frequency at the time.

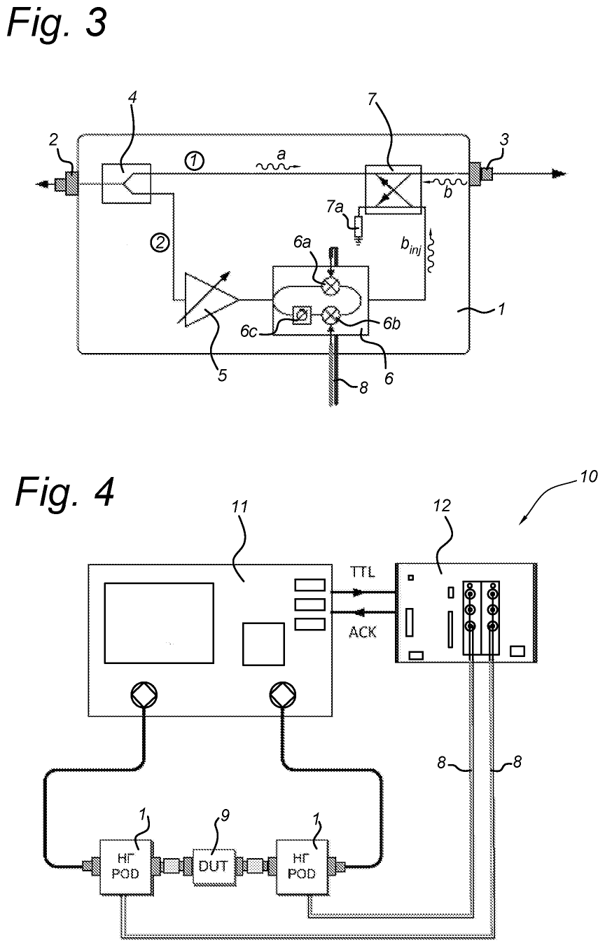

The present invention embodiments provide solutions to the disadvantages associated with prior art set-ups as discussed above. FIG. 3 shows a schematic diagram of a DUT interface device 1 (or High Gamma pod, HΓ-pod) according to an embodiment of the present invention, and FIG. 4 shows the system 10 set-up for executing test of a DUT 9 with a vector network analyser 11, in a two-port configuration. Each DUT interface device 1 is a two port device, allowing to realize a signal cancellation loop, and allowing its use with any commercially available multiport VNA 11.

In general, the present invention relates to a device under test (DUT) interface device 1 (or high gamma (HΓ)-pod) for connecting a vector network analyser 11 to a device under test 9. The DUT interface device 1 comprises an analyser terminal 2, a DUT terminal 3, and a control input terminal 8. A divider/coupler component 4 is present having a main terminal connected to the analyser terminal 2, a variable gain amplifier 5 is connected to a first branch terminal of the divider/coupler component 4, and an I/Q mixer 6 is present having an input terminal connected to an output terminal of the variable gain amplifier 5. Furthermore, a bridge/coupler component 7 is present, of which first branch terminals are connected between a second branch terminal of the divider/coupler component 4 and the DUT terminal 3 for providing a test signal a to the DUT terminal 3, and second branch terminals are connected between an output of the I/Q mixer 6 and a grounding impedance 7a. Such a DUT interface device 1 having all relevant elements for the intended purpose, allows a connection close to the DUT 9, and hence a better performance for measurements, as the relevant leads and connections are close to the DUT 9.

In a further embodiment, an additional power amplifier may be added receiving an output from the I/Q mixer 6, and providing an amplified signal to the bridge/coupler component 7. This allows to further optimize the I/Q linearity.

In an embodiment, the I/Q mixer 6 is arranged to generate an injection signal bᵢₙⱼ which is coherently combined with a reflected signal b received on the DUT terminal 3. Again, as this takes place in the DUT interface device 1 close to the DUT, it will be less likely that errors or interference occurs. More in particular, the cancellation is close to the DUT 9 thus the sensitivity of the cancellation condition, due to vibration or changes in the setup is less pronounced. In an even further embodiment, the I/Q mixer 6 (and optionally the variable gain amplifier 5) is connected to the control input terminal 8. This allows to use proper wiring to run to the DUT interface device 1, which as a result will be less susceptible to distortion or other error introducing effects. Since all the loops are incorporated near the DUT 9, the LO and RF path are coupled, thus creating phase fluctuation (which in effect are the ones leading to the errors in the interferences) coherent which do ratio out in the cancellation condition.

In an even further embodiment, the variable gain amplifier 5 comprises a plurality of variable attenuators. The presence of the variable gain amplifier 5, possibly in the form of variable or switchable attenuators, allows to independently control power between the RF signal to the DUT 9 and the local oscillator signal in the I/Q mixer 6, which allows to optimize the drive level of the I/Q mixer 6 and at the same time providing independent power control towards the DUT 9 (via the signal generated from the analyser terminal 2). In an even further embodiment this is implemented using an integrated circuit digitally controlled variable attenuator, obviating any switching parts.

A simplified schematic view of the DUT interface device 1 (HF pod) according to a present invention embodiment is shown in FIG. 3. The DUT interface device 1 comprises two terminals 2, 3 and a control signal input 8, as a single, compact unit. In the DUT interface device 1, after the input terminal 2 a high directivity power divider/coupler 4 is placed to split the test signal a wave between two different paths (indicated by numerals 1 and 2 in circles). In other terms, the divider/coupler component (4) is a high directivity power divider/coupler splitting a test signal on the main terminal over the first and second branch terminal.

In the specific embodiment shown in FIG. 3, the signal at port 1 of the divider/coupler 4 serves as test signal a to stimulate the DUT 9 via output terminal 3. The signal at port 2 of the divider/coupler 4 is used to generate the phase coherent cancellation signal bᵢₙⱼ required to cancel the scattered wave b originating from the DUT 9 during the execution of a test. The split signal part (or wave) at port 2 of the divider coupler 4 is first amplified, using a variable gain amplifier 5, to an adequate level (i.e., to toggle the switching core of the mixer) and is then used as the local oscillator (LO) signal of an IQ mixer 6. The IQ mixer 6 comprises internal components (mixers 6a, 6b and phase shifter 6c) which as such are known to the person skilled in the art.

As mentioned above, in a further embodiment, an additional (variable gain) amplifier is added at the output of the IQ mixer. This allows to optimize the linearity of the I/Q mixer 6, e.g. by not having the output of the I/Q mixer 6 go higher than the optimal linear range of the mixer (and using the additional amplifier to get a sufficiently high signal level. Also, it is then possible to keep the output of the I/Q mixer 6 at a sufficiently high level (not at levels comparable to DC signal noise levels (quantization noise), even if a lower level is desired at the bridge/coupler component 7 (then using an attenuation by the additional amplifier).

As shown in the system view of FIG. 4, the in-phase (V_{I}) and quadrature-phase (V_{Q}) signals of the control signal input 8 are sourced with accurate DC signals generated with high bit count digital to analogue converters (DACs) in DAC signal generator 12. The V_{I} and V_{Q} signals are used to steer the phase and control the amplitude of the injection signal (i.e., Cartesian modulation). The generated cancellation signal bᵢₙⱼ is injected into path 1 of the divider coupler 4 in the same direction of the scattered wave b with a high directivity coupler 7 (of which the fourth port is coupled to a termination impedance 7a). The VNA 11 and the DAC signal generator 12 are placed inside a trigger/acknowledge loop using the indicated TTL and acknowledge (ACK) signal. During a frequency sweep the VNA 11 will change internal PLL sources to the next frequency in the sweep and send a TTL trigger to the signal generator 12 to set the proper values of the control signal input signals V_{I} and V_{Q} to generate the cancellation signal bᵢₙⱼ for that specific frequency. The DAC signal generator 12 will send an ACK signal to initiate the VNA measurement. After this measurement, the VNA 11 will move to the next frequency and re-initiate the trigger/acknowledge protocol.

Therefore, the present invention in a further aspect relates to a system for executing measurements on a device under test (DUT) 9, comprising a vector network analyser 11, at least one DUT interface device 1 (HΓ-pod) according to any one of the present invention embodiments connected to an associated measuring port of the vector network analyser 11, and a control unit 12 connected to the vector network analyser 11 and to control input terminals 8 of associated ones of the at least one DUT interface device 1 (HΓ-pod). The control unit 12 is arranged to provide quadrature control signals V_{I}, V_{Q} (i.e. synchronized I/Q mixer signals) for the associated at least one DUT interface device 1, wherein the at least one DUT interface device 1 is connected directly to the device under test 9. Thus, as compared to prior art systems, the loops in the measurement system are set-up differently, which improves performance. No longer is it necessary to provide a split of signals inside the vector network analyser 11. In the prior art solution the split is very far from the actual DUT loop creating several problems for the cancellation stability. Additionally, such an approach is making it very difficult to achieve two port configuration in conventional vector network analysers.

In a further embodiment, the control unit 12 comprises (high bit count) digital-to-analogue converters to provide quadrature control signals V_{I}, V_{Q} for each of the at least one DUT interface device 1. The vector network analyser 11 is connected to the control unit 12 using a synchronization interface for executing frequency sweeps. E.g. the synchronization interface comprises a control signal (TTL) and an acknowledgment return signal (ACK), as discussed above.

According to a further aspect of the present invention, a method is provided for using a system according to any one of the embodiments described above, wherein the system comprises a DUT interface device 1 according to any one of the embodiments described herein connected to a first measuring port of the vector network analyser 11. The method comprises calibrating the system by obtaining injection signal parameters to allow measurements of a device under test 9 connected to the DUT interface device 1. Actual measurements of a device under test (DUT) 9 can then be executed by using the obtained injection signal parameters to control the DUT interface device 1 (i.e. with injection signal on).

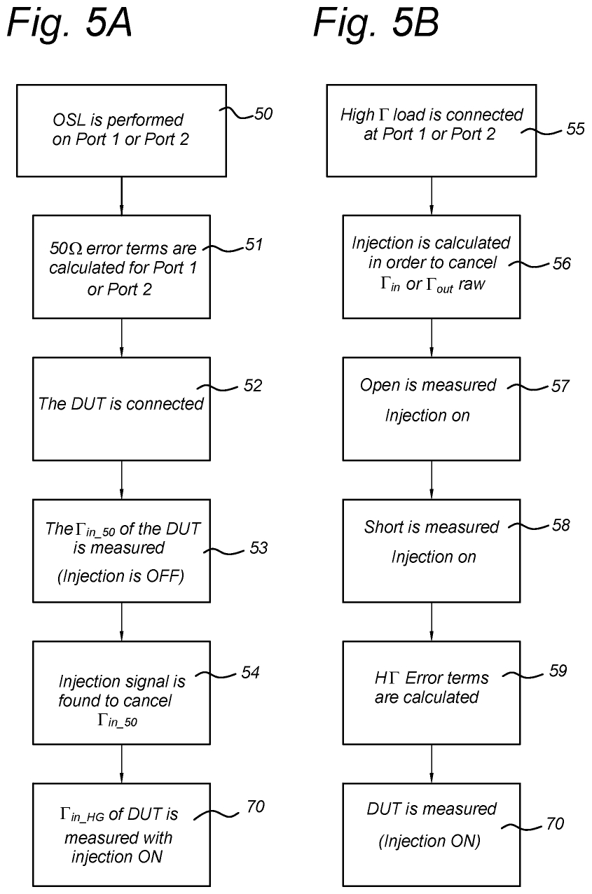

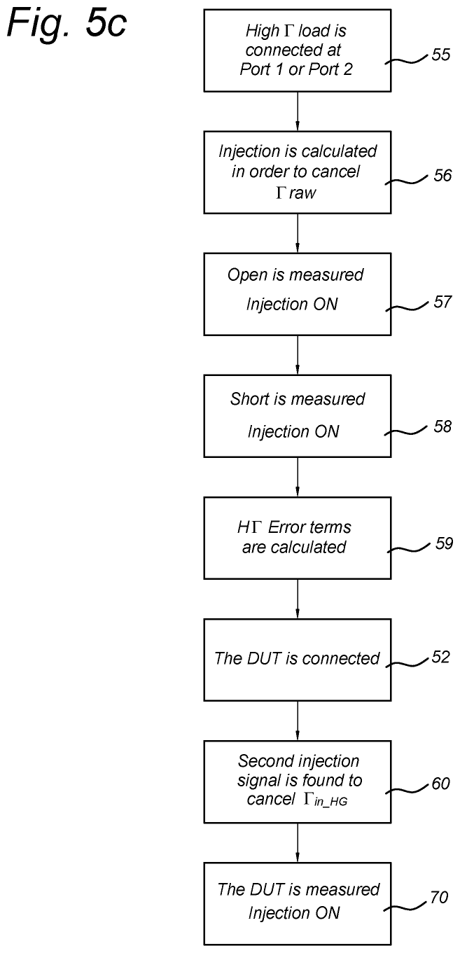

In accordance with further embodiments, one of three different calibration methods are provided to obtain various effects. In a first group of embodiments (labelled as method M1 in the following), measurement sensitivity at high gamma loads is improved (i.e. reduced trace noise), as shown in the flow schedule of FIG. 5A. In a second group of embodiments (labelled as method M2 in the following), absolute measurement accuracy at high gamma loads is improved by employing dedicated calibration structures, i.e., high gamma standards, as shown in the flow schedule of FIG. 5B. In a third group of embodiments (labelled as method M3 in the following), both absolute accuracy and sensitivity are improved by employing a combination of methods M1 and M2, as shown in the flow schedule of FIG. 5C.

The three groups of calibration procedures (methods M1, M2, M3) can be applied to a one port or a two port measurement system, following the description presented below.

Calibration method embodiments are provided for the test set-up arrangement of FIG. 4, for which the flow charts are shown in FIGS. 5A, 5B and 5C. The setup calibration is based on a short-open-load (SOL) technique, to be applied to port one of a network analyser 11 only (one port DUT 9) or both port one and two of the network analyser 11 (two ports DUT 9). In order to extract consistent error terms to allow the measurement of full two-port error corrected scattering parameters (i.e., normalized to 50Ω) the injection signals are turned on and off at specific moments during the procedure as with reference to FIGS. 5A, 5B and 5C.

FIG. 5A shows a flow chart for the first group of embodiments (method M1). This method comprises:
(block 50) perform a short-open-load calibration on the first measuring port of the vector network analyser 11 with the injection signal bᵢₙⱼ off,
(block 51) calculating 50Ω error terms (i.e., system error terms e₀₀, e₁₁, e₁₀e₀₁),
(block 52) connecting the device under test 9,
(block 53) compute input reflection coefficient Γ_{in_50} of the device under test 9 in a 50Ω environment.
(block 54) determine required quadrature control signals V_{I}, V_{Q} to minimize the input reflection coefficient Γ_{in_50} (using e.g. an iteration algorithm).

FIG. 5B shows a flow chart for the second group of embodiments (method M2), This method comprises:
(block 55) connecting a high gamma load as device under test 9 to the first measuring port of the vector network analyser 11 via the first DUT interface device 1,
(block 56) determine required quadrature control signals V_{I}, V_{Q} to minimize the reflection coefficients Γ_{raw},
(block 57 and 58) perform a short-open calibration on the first measuring port of vector network analyser 11 with the injection signal Nᵢₙⱼ on, and
(block 59) compute system error terms (e_{00_HG}, e_{11_HG}, e₁₀e_{01_HG}) in high gamma condition (i.e., injection signal on) for the first measuring port of the vector network analyser 11.

Both the method groups M1 and M2 may be applied for a two port DUT 9. To that end the system comprises a further DUT interface device connected to a second measuring port of the vector network analyser 11. The steps as described above are then repeated for the second measuring port of the vector network analyser (11).

FIG. 5C shows a flow chart for the third group of embodiments (method M3). This method comprises, in addition to the sequence of blocks 55-59 as described with reference to FIG. 5B:

connecting the further DUT interface device 1 (block 52) and then determining the second injection signal (block 60).

As shown in the flow charts of FIG. 5A-5C, the calibration steps can then be followed by an actual measurement step 70 of the DUT 9, with the injection signal(s) bᵢₙⱼ as determined in the calibration steps.

In more generic terms, a method embodiment is provided for calibrating a system according to any one of the system embodiments described herein, wherein the system comprises two DUT interface devices 1 connected to two measuring ports of the vector network analyser 11. The method comprises:
(a) connecting a high gamma load as device under test 9 to a first measuring port of the vector network analyser 11 via a first DUT interface device 1, (note that this is not used in method M1).
(b) determine required quadrature control signals V_{I}, V_{Q} to minimize the reflection coefficients Γ_{raw}, (note that this is not used in method M1).
(c) perform a short-open-load calibration on the first measuring port of the vector network analyser 11 with the injection signal bᵢₙⱼ off, (i.e. wherein the load is a standard system value, e.g. a 50Ω load).
(d) compute 50Ω system error terms e₀₀, e₁₁, e₁₀e₀₁ for the first measuring port of the vector network analyser 11,
(e) perform a short-open calibration on the first measuring port of vector network analyser 11 with the injection signal bᵢₙⱼ on (again, note that this is not used in method M1).
(f) compute HG system error terms e_{00_HG}, e_{11_HG}, e₁₀e_{01_HG} for the first measuring port of the vector network analyser 11, (note that this is not used in method M1), repeating steps (a)-(e) for the second measuring port of the vector network analyser 11.
(g) in the case of method groups M1 and M3, the procedure is followed by determining at each frequency point the required V_{I}, V_{Q} to minimize the reflection coefficients Γᵢₙ/Γₒᵤₜ of the DUT 9.

In a further embodiment, in step (b) the required quadrature signals V_{I}, V_{Q} are determined for a range of frequencies of interest, i.e. a number of discrete frequencies in a frequency range. The method may further comprise computing two-port scattering parameters of the high gamma load as device under test 9 by using a thru connection between the first and second measuring port of the vector network analyser 11, with the injection signal (bᵢₙⱼ) off. These method embodiments are specifically advantageous in that both measurement ports are being calibrated, taking into account specific issues in relation to the use of two measurement ports of the vector network analyser 11.

The above mentioned generic calibration method embodiments are clarified and further detailed in the following description.

The widely used short-open-load (SOL) method for calibration of one-port vector network analysers relies on three pre-characterized calibration devices used as device under test 9. The transfer function between uncorrected Γraw and corrected Γ reflection coefficient is determined through three error terms e₀₀, e₁₁, and e₁₀e₀₁, and Γ at the calibration reference plane can be calculated using the following expression:

$$Γ = \frac{{Γ}_{raw} - {e}_{00}}{{e}_{10} {e}_{01} + {e}_{11} \cdot ( {Γ}_{raw} - {e}_{00} )} \qquad ( 1 )$$

Here, the error terms e₀₀, e₁₁, and e₁₀e₀₁ respectively represent directivity, source match, and reflection tracking of the calibrated VNA 11. The SOL method relies on the use of three calibration devices with known electrical properties Γᵢ, resulting in three independent measurements Γ_{raw(i)} with three unknown error-terms, which are calculated using the following equation:

$$[ \begin{matrix}1 & {Γ}_{1} \cdot {Γ}_{raw 1} & - {Γ}_{1} \\ 1 & {Γ}_{2} \cdot {Γ}_{raw 2} & - {Γ}_{2} \\ 1 & {Γ}_{3} \cdot {Γ}_{raw 3} & - {Γ}_{3}\end{matrix} ] \cdot [ \begin{matrix}{e}_{00} \\ {e}_{11} \\ Δ\end{matrix} ] = [ \begin{matrix}{Γ}_{raw 1} \\ {Γ}_{raw 2} \\ {Γ}_{raw 3}\end{matrix} ] \\ Δ = {e}_{00} {e}_{11} - {e}_{10} {e}_{01} \qquad ( 2 )$$

The calibration procedure is as follows (see also flow charts of FIGS. 5B and 5C):

The impedance standard of interest HighGamma_{load} (HΓ) is connected to the system test-port (block 55). The measurement software uses an iteration algorithm (e.g. the Newton-Raphson algorithm. as such known to the person skilled in the art) to minimize Γ_{raw} to zero (e.g. at every desired frequency, block 56) and stores the corresponding V_{I}(f) and V_{Q}(f) values (this step does not apply to calibration method M1, see FIG. 5A).

A first SOL calibration with injection signal bᵢₙⱼ turned off is performed (applies to all method groups M1-M2-M3).

A conventional SOL calibration method is used (block 59) for calculation of system error terms, see equation (2), with injection off (e_{term_50}).

The second SOL calibration is performed with the measurement of three calibration devices with suitable electrical properties to improve accuracy over the impedance measurement range of interest, the HΓ, and two other known device typically the short (S) and the open (O). This applies to method groups M2 and M3 only. Again, a conventional SOL calibration method is used for calculation of system error terms, see equation (2), with injection on (e_{term_HG}).

The standard definition of the short and the open is converted in the gamma plane of the new reference impedance, i.e., where HighGamma_{load} (HΓ) is now zero. Considering Z₁ the original reference impedance and Z₂ the new reference impedance, the scattering matrix Sᵢ associated to either the short or the open standard in Z₁ is converted in the new reference plane using the equation:

S′=P⁻¹(S−γ)(1−γS)⁻¹P

wherein:

$$P = \sqrt{\frac{Re ( {Z}_{1} )}{Re ( {Z}_{2} )}} \vert \frac{{Z}_{1}}{{Z}_{2}} \vert \frac{2 {Z}_{1}}{{Z}_{1} + {Z}_{2}}$$

$$γ = \frac{{Z}_{2} - {Z}_{1}}{{Z}_{2} + {Z}_{1}}$$

and S is the scattering matrix in the old reference system and S′ is the new reference system (i.e., high gamma), I is the identity matrix.
The same procedure is then repeated for port two.

With the system error-terms known, equation (1) is used to correct the input and output reflection coefficient of the high gamma device with injection on.

In order to compute the two-ports scattering parameters of the extreme gamma device the load match (e₂₂) and transmission tracking term (e₁₀e₃₂) are then computed.

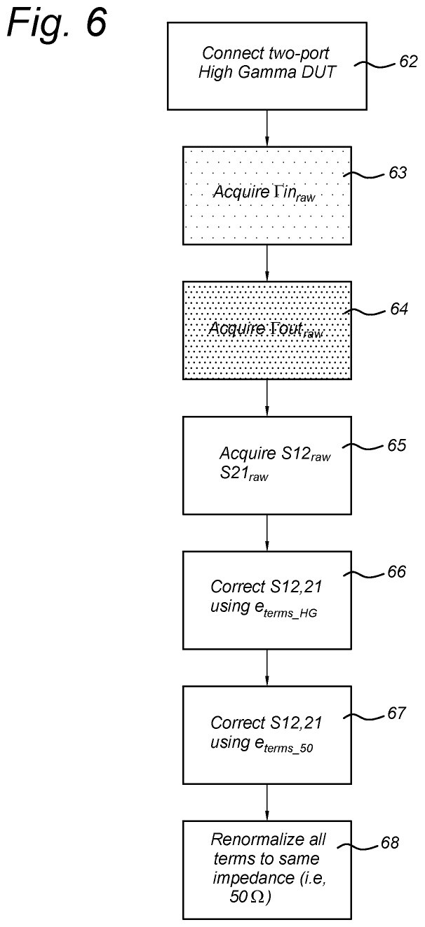

In order to obtain improved two port parameters of a high Γ device (i.e., reduced mismatched uncertainty and increased absolute accuracy of the reflection coefficients, using method group M3), after the above described calibration the measurement procedure is as follows, see FIG. 6 for the flow graph representation:

0) Connect the two-port high Γ DUT 9 (step 62)

1) Turn on the cancellation signal at port one, and acquire the raw input reflection coefficient Γ_{INraw} (step 63, sparse dot pattern)

2) Turn on the cancellation signal at port two, and acquire the raw output reflection coefficient Γ_{OUTraw} (step 64, dense dot pattern)

3) Turn the injection signals off and acquire S12_{raw} and S21_{raw} (step 65)

4) Correct the input/output reflection coefficients (Γ_{IN} and Γ_{OUT}) using eq. (1) and e_{term_HG} (step 66)

5) Correct the S21 and S12 using two port calibration equation (see above) and e_{term_50} (step 67)

5) Use the following eq. (4) to obtain the normalized scattering parameters of the high Γ DUT 9 (step 68)

$${s}_{11} = \frac{1}{2} \frac{1}{{e}_{22 R} ( {e}_{22 F} {Γ}_{OUT} - 1 )} ( {e}_{22 F} {e}_{22 R} {Γ}_{IN} {Γ}_{OUT} + {Γ}_{OUT} {e}_{22 F} - {e}_{22 R} {Γ}_{IN} - 1 ++ \sqrt{( {e}_{22 R} {Γ}_{IN} - 1 ) ( {e}_{22 F} {Γ}_{OUT} - 1 ) ( \begin{matrix}{e}_{22 F} {e}_{22 R} {Γ}_{IN} {Γ}_{OUT} + \\ 4 {e}_{22 F} {e}_{22 R} {s}_{12} {s}_{21} - \\ {Γ}_{OUT} {e}_{22 F} - {e}_{22 R} {Γ}_{IN} + 1\end{matrix} )} ) \\ {s}_{22} = {Γ}_{OUT} - \frac{{s}_{12} {s}_{21} {e}_{22 R}}{1 - {s}_{11} {e}_{22 R}} \qquad ( 4 )$$

Where the error terms in (4) are e_{term_50}.

If the method M1 is applied for a two port DUT 9 measurement (using a further DUT interface device 1) the following method steps may also describe this method M1:
connecting a high gamma load as device under test 9 to the two measuring ports of the vector network analyser 11 via associated DUT interface devices 1, (block 62);
acquiring corrected two port S-parameters of the DUT with injection off, and using 50Ω error terms, derive the V_{I} and V_{Q} signals to cancel the corrected input and output reflection coefficient, i.e., identify the cancellation signal bᵢₙⱼ. Furthermore, renormalizing the S-parameter to a given reference impedance may be performed (block 68).

Also method M2 may be applied for a two-port DUT 9, with the following modifications to the method M2 (with reference to the blocks identified in FIG. 6):
acquiring corrected Γ_{IN} and Γ_{OUT} parameters of the DUT with injection on, and using the High Gamma error terms (block 63, 64),
acquiring scattering parameters S12_{raw}, S21_{raw} with injection signals bᵢₙⱼ to both measuring ports off (block 65),
correcting the acquired parameters using the system error terms obtained from the method for calibration (block 66, 67),
obtaining normalized scattering parameters for the high gamma load as device under test 9 (block 68).

The method group M3 can in this respect be seen as a repeat of the procedure of method group M2 and then derive the V_{I} and V_{Q} signals to cancel the corrected input and output reflection coefficient, i.e., identify the cancellation signal b_{inj,} followed by renormalizing the S-parameter to a given reference impedance.

When considering a frequency sweep of the DUT 9, due to the reactive parasitic and delays involved, the measured impedance (at any port) will vary versus frequency, in many cases going from a high gamma value at lower frequencies to a lower gamma value at higher frequencies.

In a further embodiment of the present invention, a decision making algorithm is added to the method embodiments, based on the system sensitivity. The decision making algorithm was developed to choose, during the post processing phase of the measurement, which data will provide a lower uncertainty.

The algorithm is based on computing the derivative of the magnitude of the reflection coefficient (normalized to 50Ω) in respect of the magnitude of Z, this quantity will be defined as Δ. The system settings (injection off versus injection on) providing the highest value of Δ for any given impedance will provide the highest sensitivity and thus lowest uncertainty, and will be used to further process the data. Thus, in a further embodiment of the measurement method the measurement of a device under test (DUT) is executed at a predetermined frequency with or without injection signals bᵢₙⱼ in dependence of a sensitivity parameter Δ, the sensitivity parameter Δ being defined as the derivative of the magnitude of the reflection coefficient Γ in respect of the magnitude of the load impedance Z.

In an example Δ is computed for a (standard) 50Ω system and the system with injection on (i.e., 1 KΩ in the specific case). Depending on the value of Δ the data from the 50Ω system may provide a higher sensitivity, or the data from the 1 KΩ system will provide a higher sensitivity, and a selection is made accordingly.

It is noted that the present invention embodiments are advantageously applicable when the high gamma load, in operation, has a high voltage standing wave ratio (as compared to normal system impedance of 50Ω), e.g. a voltage standing wave ratio is higher than 9.

The present invention has been described above with reference to a number of exemplary embodiments as shown in the drawings. Modifications and alternative implementations of some parts or elements are possible, and are included in the scope of protection as defined in the appended claims.

1. A device under test (DUT) interface device for connecting a vector network analyser to a device under test, comprising
an analyser terminal, a DUT terminal, and a control input terminal,
a divider/coupler component having a main terminal connected to the analyser terminal,
a variable gain amplifier connected to a first branch terminal of the divider/coupler component,
an I/Q mixer having an input terminal connected to an output terminal of the variable gain amplifier,
a bridge/coupler component, of which first branch terminals are connected between a second branch terminal of the divider/coupler component and the DUT terminal for providing a test signal (a) to the DUT terminal, and second branch terminals are connected between an output of the I/Q mixer and a grounding impedance.

2. The DUT interface device according to claim 1, wherein the divider/coupler component is a high directivity power divider/coupler splitting a test signal on the main terminal over the first and second branch terminals.

3. The DUT interface device according to claim 1, wherein the I/Q mixer is arranged to generate an injection signal (binj) which is coherently combined with a reflected signal (b) received on the DUT terminal.

4. The DUT interface device according to claim 1, wherein the I/Q mixer is connected to the control input terminal.

5. The DUT interface device according to claim 1, wherein the variable gain amplifier comprises a plurality of variable attenuators.

6. A system for executing measurements on a device under test (DUT, 9) comprising a vector network analyser, at least one DUT interface device according to claim 1 connected to an associated measuring port of the vector network analyser, and
a control unit connected to the vector network analyser and to control input terminals of associated ones of the at least one DUT interface device, wherein the control unit is arranged to provide quadrature control signals (V_{I}, V_{Q}) for the associated at least one DUT interface device,
wherein the at least one DUT interface device is connected directly to the device under test (DUT, 9).

7. The system according to claim 6, wherein the control unit comprises digital-to-analogue converters to provide quadrature control signals (V_{I}, V_{Q}) for each of the at least one DUT interface device.

8. The system according to claim 7, wherein the vector network analyser is connected to the control unit using a synchronization interface for executing frequency sweeps.

9. The system according to claim 8, wherein the synchronization interface comprises a control signal (TTL) and an acknowledgment return signal (ACK).

10. A method for using a system according to claim 6, wherein the system comprises a DUT interface device according to claim 1 connected to a first measuring port of the vector network analyser, comprising
calibrating the system by obtaining injection signal parameters to allow measurements of a device under test connected to the DUT interface device.

11. The method according to claim 10, further comprising
(a) perform a short-open-load calibration on the first measuring port of the vector network analyser with the injection signal (bᵢₙⱼ) off,
(b) calculating 50Ω error terms,
(c) connecting the device under test,
(d) compute input reflection coefficient Γ_{in_50} of the device under test in a 50Ω environment and determine required quadrature control signals (V_{I}, V_{Q}) to minimize the input reflection coefficient Γ_{in_50}.

12. The method according to claim 10, further comprising
(a) connecting a high gamma load as device under test to the first measuring port of the vector network analyser via the first DUT interface device,
(b) determine required quadrature control signals (V_{I}, V_{Q}) to minimize the reflection coefficients (Γ_{raw}),
(c) perform a short-open calibration on the first measuring port of vector network analyser with the injection signal (bᵢₙⱼ) on, and
(d) compute system error terms (e_{00_HG}, e_{11_HG}, e₁₀e_{01_HG}) for the first measuring port of the vector network analyser.

13. The method according to claim 11, wherein the system comprises a further DUT interface device according to claim 1, wherein the further DUT interface device is connected to a second measuring port of the vector network analyser, the method further comprising
repeating steps (a)-(d) for the second measuring port of the vector network analyser.

14. The method according to claim 10, further comprising,
connecting a high gamma load as device under test to the first and second measuring port of the vector network analyser via the associated DUT interface devices,
acquiring raw input reflection coefficients (Γ_{INraw}) on the first measuring port of the vector network analyser using the associated injection signal (bᵢₙⱼ),
acquiring raw output reflection coefficients (Γ_{OUTraw}) on the second measuring port of the vector network analyser using the associated injection signal (bᵢₙⱼ),
acquiring scattering parameters (S12_{raw}, S21_{raw}) with injection signals (bᵢₙⱼ) to both measuring ports off,
correcting the acquired parameters using the system error terms obtained from the calibration method step,
obtaining normalized scattering parameters for the high gamma load as device under test.

15. The method according to claim 10, wherein measurement of a device under test (DUT) is executed at a predetermined frequency with or without injection signals (bᵢₙⱼ) in dependence of a sensitivity parameter (Δ), the sensitivity parameter (Δ) being defined as the derivative of the magnitude of the reflection coefficient (Γ) in respect of the magnitude of the load impedance (Z).

16. The method according to claim 10, wherein the high gamma load, in operation, has a high voltage standing wave ratio.

17. The method according to claim 16, wherein the voltage standing wave ratio is higher than 9.
